(19) United States
(12) Patent Application Publication
(10) Pub. No.: US 2005/0110134 A1
(43) Pub. Date: May 26, 2005

(54) Electronic circuit unit with semiconductor components disposed on both surfaces of board

(75) Inventor: Kenichi Tanoue, Fukushima-ken (JP)

Correspondence Address: BRINKS HOFER GILSON & LIONE, P.O. BOX 10395, CHICAGO, IL, 60610, US

(73) Assignee: ALPS ELECTRIC CO., LTD.

(21) Appl. No.: 10/988,737

(22) Filed: Nov. 15, 2004

(30) Foreign Application Priority Data
Nov. 20, 2003 (JP) 2003-391153

(51) Int. Cl. H01L 23/02

(52) U.S. Cl. 257/723

(57) ABSTRACT

In an electronic circuit unit a concave portion housing a semiconductor component is provided on the rear surface of a circuit board and the disposed inside the concave portion in a state where the bottom portion of the semiconductor component is not protruded externally from the lower end of the concave portion. A different semiconductor component can be thermally compressed to the front surface side of the circuit board in a state where the lower end of the circuit board comes in contact with a jig and the circuit board is thus stably supported.

### BACKGROUND OF THE INVENTION

1. Field of the Invention

The present invention relates to an electronic circuit unit suitable for an electronic apparatus such as a transceiver, etc.

2. Description of the Related Art

A conventional electronic circuit unit is described with reference to figures. FIG. 7 is a cross-sectional view illustrating a part of the conventional electronic circuit unit, FIG. 8 is a cross-sectional view illustrating an important part of the conventional electronic circuit unit, FIG. 9 is an explanatory diagram illustrating a first process of assembling a semiconductor component in the conventional electronic circuit unit, and FIG. 10 is an explanatory diagram illustrating a second process of assembling a semiconductor component in the conventional electronic circuit unit.

Next, a structure of the conventional electronic circuit unit is described with reference to FIG. 7. A wiring pattern 52 having land portions 52a is provided on one surface (front surface) of a plate-shaped circuit board 51.

In a semiconductor component 53, a plurality of electrodes 54 is provided on the lower surface thereof and metal bumps 55 are provided on the electrodes 54. The electrodes 54 are connected to the land portions 52a through the metal bumps 55 heated and pressed (thermally compressed), so that the semiconductor component 53 is disposed on one surface of the circuit board 51.

Although not shown here, various electronic components are mounted on the one surface of the circuit board 51 and desired electrical circuits are formed in the circuit board 51, thereby forming the conventional electronic circuit unit (for example, see Patent Document 1).

The conventional electronic circuit unit in which the semiconductor component 53 is mounted on one surface of the circuit board 51 could not accomplish decrease in size of the electronic circuit unit. Therefore, in order to solve this problem, as shown in FIG. 8, the conventional electronic circuit unit could accomplish decrease in its size, by distributing and providing a plurality of semiconductor components 53a and 53b on both the front surface 51a and the rear surface 51b of the plate-shaped circuit board 51.

Next, an assembly method of the semiconductor components 53a and 53b in the electronic circuit unit is described. First, in a first process, as shown in FIG. 9, the rear surface 51b of the circuit board 51 is placed on the flat surface of a first jig 56, and then metal bumps 55 provided on the electrodes 54 of the first semiconductor component 53a are placed on the land portions 52a provided on the front surface 51a of the circuit board 51.

Next, by pressing the first semiconductor component 53a with a second jig 57 in a state where the metal bumps 55 are heated, the metal bumps 55 are bonded to the land portions 52a, and the electrodes 54 and the land portions 52a are thus connected to each other through the metal bumps 55.

Next, in a second process, as shown in FIG. 10, the circuit board 51 in which the first semiconductor component 53a has been completely assembled is reversed and the flat surface of the first semiconductor component 53a is placed on the first jig 56.

Next, the metal bumps 55 provided on the electrodes 54 of the second semiconductor component 53b are placed on the land portions 52a provided on the rear surface of the circuit board 51. Thereafter, by pressing the second semiconductor component 53b with the second jig 57 in a state where the metal bumps 55 are heated, the metal bumps 55 are bonded to the land portions 52a, and the electrodes 54 and the land portions 52a are thus connected to each other through the metal bumps 55.

In this way, the semiconductor components 53a and 53b are completely assembled onto both the front and rear surfaces of the circuit board 51. However, in the second process shown in FIG. 10, since the first semiconductor component 53a is in contact with the first jig 56, the circuit board 51 might be inclined when the second semiconductor component 53b is pressed, thereby making the support thereof unstable. Therefore, any variation might be caused in the attachment state of the metal bumps 55 of the second semiconductor component 53b to the land portions 52a.

In order to remove the inclination of the circuit board 51, it can be considered that a pressing portion for supporting the circuit board 51 is provided in the first jig 56. However, in this case, there are various kinds of circuit boards 51 depending upon kinds of products and thus it is necessary to prepare a plurality of first jigs 56 corresponding to various kinds of circuit boards 51, thereby causing increase in cost and deterioration in productivity.

[Patent Document 1] Japanese Patent Application Laid-open No. 2001-60602

In the conventional electronic circuit unit, since the first and second semiconductor components 53a and 53b are connected to the land portions 52a by thermal compression on both the front and rear surfaces of the plate-shaped circuit board 51, the first semiconductor component 53a comes in contact with the first jig 56 during the second process of assembling the second semiconductor component 53b, so that the circuit board 52 might be inclined when the second semiconductor component 53b is pressed and the support thereof becomes unstable. Therefore, any variation in the attachment state of the metal bumps 55 of the second semiconductor component 53b to the land portions 52a might be generated, thereby causing a problem that connection failure results from the metal bumps 55.

In order to remove the inclination of the circuit board 51, it can be considered that a pressing portion for supporting the circuit board 51 is provided in the first jig 56. However, in this case, there are various kinds of circuit boards 51 depending upon kinds of products and thus it is necessary to prepare a plurality of first jigs 56 corresponding to various kinds of circuit boards 51, so that there is a problem that deterioration in productivity as well as increase in cost is caused.

### SUMMARY OF THE INVENTION

It is thus an object of the present invention to provide an electronic circuit unit which is excellent in productivity and is low in cost and which has reliable connection between electrodes and land portions.

According to the first solving means of the present invention for achieving the above object, there is provided an electronic circuit unit comprising a circuit board formed by stacking a plurality of substrates, a wiring pattern having land portions provided on both the front and rear surfaces of the circuit board, and a semiconductor component disposed on both the front and rear surfaces of the circuit board and connected to the land portions through connection conductors by thermal compression, wherein a concave portion for housing the semiconductor component is provided on the rear surface of the circuit board and the semiconductor component is disposed inside the concave portion in a state where the bottom portion of the semiconductor component is not protruded externally from the lower end of the concave portion.

According to the second solving means of the present invention, at least a pair of wall portions disposed to be opposite to each other with a gap therebetween may be provided on the rear surface of the circuit board, and the concave portion may be formed between the pair of wall portions.

According to the third solving means of the present invention, a ring-shaped wall portion may be provided on the rear surface of the circuit board to surround the outer circumference of the concave portion.

According to the fourth solving means of the present invention, the semiconductor component may be made of a flip chip.

According to the fifth solving means of the present invention, the connection conductors may be made of metal bumps.

The electronic circuit unit according to the present invention comprises a circuit board formed by stacking a plurality of substrates, a wiring pattern having land portions provided on both the front and rear surfaces of the circuit board, and a semiconductor component disposed on both the front and rear surfaces of the circuit board and connected to the land portions through connection conductors by thermal compression, wherein a concave portion for housing the semiconductor component is provided on the rear surface of the circuit board and the semiconductor component is disposed inside the concave portion in a state where the bottom portion of the semiconductor component is not protruded externally from the lower end of the concave portion.

In this way, since the semiconductor component of the rear surface side is housed in the concave portion of the circuit board, a semiconductor component can be thermally compressed to the front surface side of the circuit board in a state where the lower end of the circuit board comes in contact with a jig and the circuit board is thus stably supported, so that the attachment state of the connection conductors at the side of the semiconductor component positioned on the front surface side of the circuit board to the land portions is good. Therefore, it is possible to obtain reliable attachment.

Since stable support can be obtained from the circuit board itself, it is not necessary to prepare jigs corresponding to various kinds, so that it is possible to obtain an electronic circuit unit with reduced cost and enhanced productivity.

Since at least a pair of wall portions disposed to be opposite to each other with a gap therebetween is provided on the rear surface of the circuit board and the concave portion is formed between the pair of wall portions, it is possible to obtain an electronic circuit unit having a simple structure and a large area of the rear surface side.

since a ring-shaped wall portion is provided on the rear surface of the circuit board to surround the outer circumference of the concave portion, the support by the jig at the rear surface side of the circuit board can become more stable and reliable.

Since the semiconductor component is made of a flip chip, the semiconductor component's cost is reduced and it is thus possible to obtain an electronic circuit unit with reduced cost.

Since the connection conductors are made of metal bumps, the connection can be made reliably.

### BRIEF DESCRIPTION OF THE DRAWINGS

FIG. 1 is a perspective view illustrating an electronic circuit unit according to a first embodiment of the present invention;

FIG. 2 is a perspective view illustrating the electronic circuit unit according to the first embodiment of the present invention as seen from the rear surface side;

FIG. 3 is a cross-sectional view illustrating a main part of the electronic circuit unit according to the first embodiment of the present invention;

FIG. 4 is an explanatory diagram illustrating a first process of assembling a semiconductor component in the electronic circuit unit according to the first embodiment of the present invention;

FIG. 5 is an explanatory diagram illustrating a second process of assembling a semiconductor component in the electronic circuit unit according to the first embodiment of the present invention;

FIG. 6 is a perspective view illustrating the electronic circuit unit according to a second embodiment of the present invention as seen from the rear surface side;

FIG. 7 is a cross-sectional view illustrating a part of a conventional electronic circuit unit;

FIG. 8 is a cross-sectional view illustrating a main part of the conventional electronic circuit unit;

FIG. 9 is an explanatory diagram illustrating a first process of assembling a semiconductor component in the conventional electronic circuit unit; and

FIG. 10 is an explanatory diagram illustrating a second process of assembling a semiconductor component in the conventional electronic circuit unit.

### DESCRIPTION OF THE PREFERRED EMBODIMENT

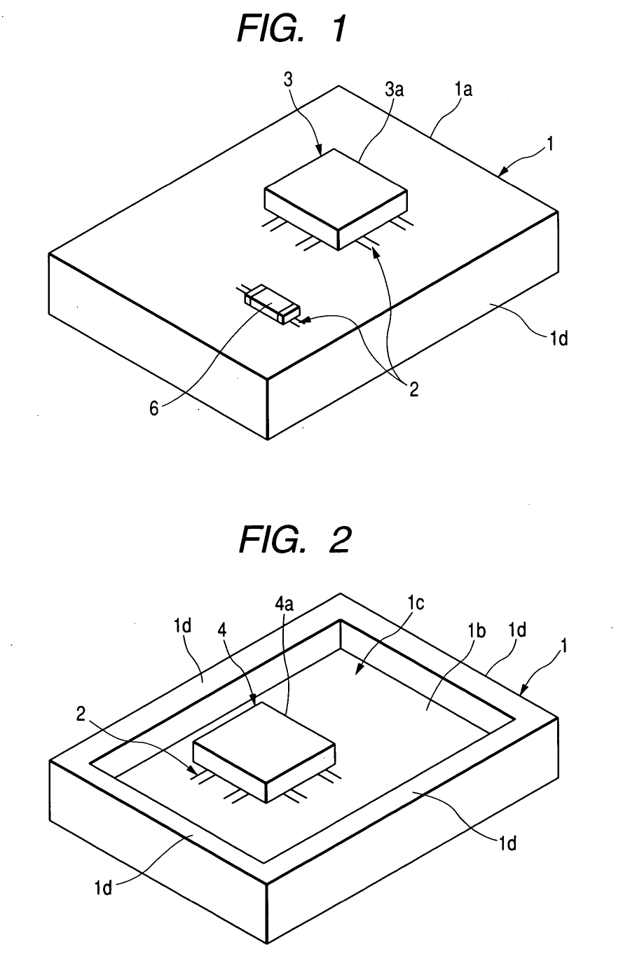

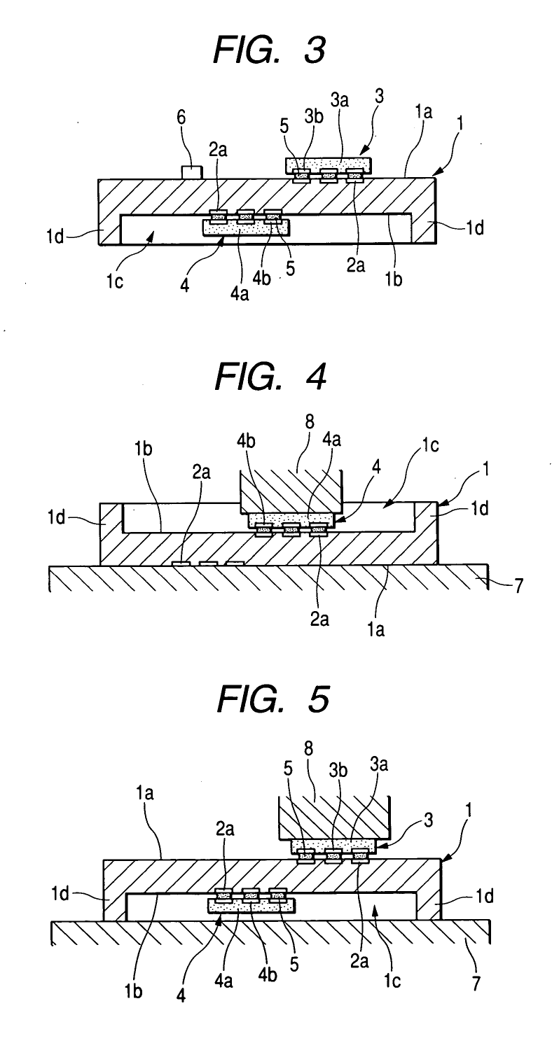

Hereinafter, an electronic circuit unit according to the present invention will be described with reference to the figures. FIG. 1 is a perspective view illustrating an electronic circuit unit according to a first embodiment of the present invention, FIG. 2 is a perspective view illustrating the electronic circuit unit according to the first embodiment of the present invention as seen from the rear surface side, and FIG. 3 is a cross-sectional view illustrating a main part of the electronic circuit unit according to the first embodiment of the present invention.

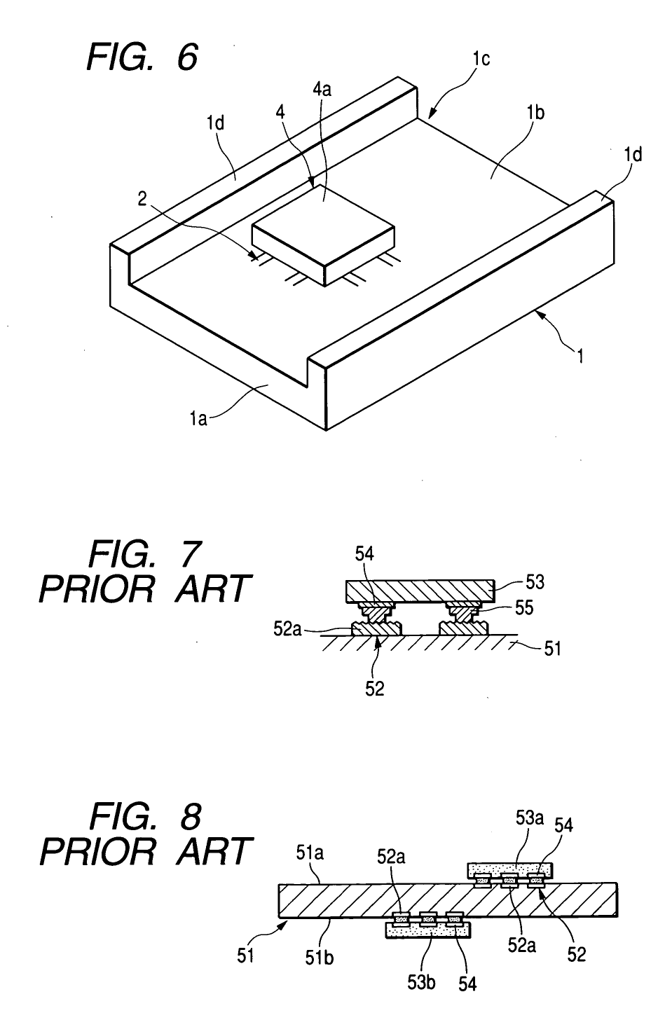

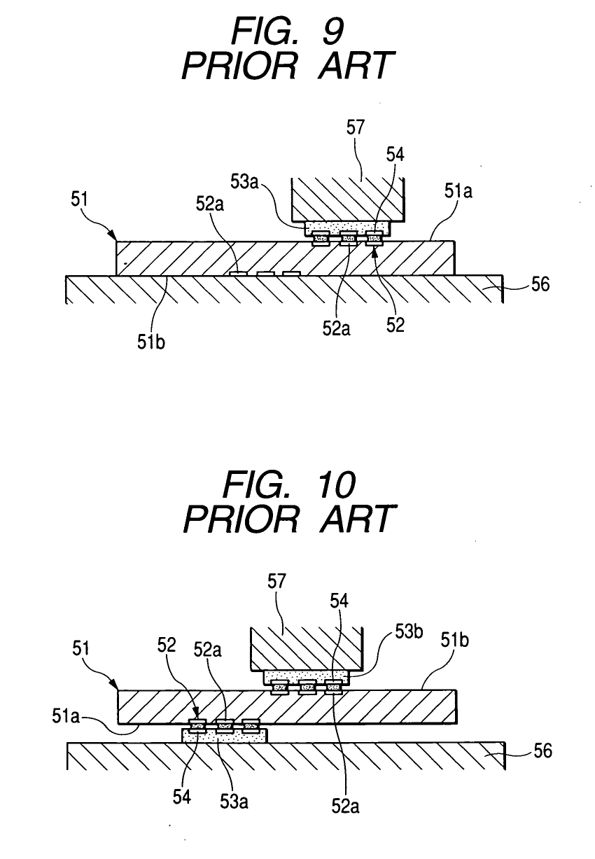

FIG. 4 is an explanatory diagram illustrating a first process of assembling a semiconductor component in the electronic circuit unit according to the first embodiment of the present invention, FIG. 5 is an explanatory diagram illustrating a second process of assembling a semiconductor component in the electronic circuit unit according to the first embodiment of the present invention, and FIG. 6 is a perspective view illustrating an electronic circuit unit according to a second embodiment of the present invention as seen from the rear surface side.

Next, the structure of the electronic circuit unit according to the first embodiment of the present invention will be described with reference to FIGS. 1 to 3. The circuit board 1 formed by stacking a plurality of substrates comprises a flat front surface (one surface) 1a, a concave portion 1c provided at a rear surface side (the other surface) 1b, and a ring-shaped wall portion 1d made of a part of the circuit board provided to surround the other circumference of the concave portion 1c.

A wiring pattern 2 is provided on the front surface 1a and the rear surface 1b of the circuit board 1 and in the intermediate layer therebetween, and the land portions 2a are provided in the wiring pattern 2 provided on the front surface 1a and the rear surface 1b of the circuit board 1.

First and second semiconductor components 3 and 4 made of a flip chip, etc. have a body portion 3a, 4a and a plurality of electrodes 3b, 4b provided on the lower surface of the body portion 3a, 4a. Connection conductors 5 made of metal bumps, ball grid arrays, etc. are provided on the electrodes 3b, 4b.

At the front surface side 1a of the circuit board 1, the electrodes 3b of the plural first semiconductors 3 are connected to the land portions 2a through the connection conductors 5 to be heated and pressed (thermally compressed). At the rear surface side 1b of the circuit board 1, at least one second semiconductor component 4 is housed in the concave portion 1c, and the electrodes 4b of the second semiconductor component 4 are connected to the land portions 2a through the connection conductors 5 to be heated and pressed (thermally compressed).

At this time, the bottom portion (bottom portion of the body portion 4a) of the second semiconductor component 4 housed in the concave portion 1c is not externally protruded from the lower end of the concave portion 1c, that is, the bottom portion is not downwardly protruded from the lower end of the wall portion 1d.

The land portions 2a positioned on the front and rear surfaces 1a and 1b of the circuit board 1 are mounted with various electronic components 6 including capacitors or resistors of a chip shape, etc, and desired electrical circuits are formed on the circuit board 1, thereby forming the electronic circuit unit according to the present invention.

A method of assembling the first and second semiconductor components 3 and 4 in the electronic circuit unit will be now described with reference to FIGS. 4 and 5. First, in a first process, as shown in FIG. 4, the front surface 1a of the circuit board 1 is placed on the flat surface of a first jig 7 and the connection conductors 5 provided on the electrodes 4b of the second semiconductor component 4 are placed on the land portions 2a provided on the rear surface 1b of the circuit board 1.

Next, by pressing the body portion 4a of the second semiconductor component 4 with a second jig 8 in a state where the connection conductors 5 are heated, the connection conductors 5 are bonded to the land portions 2a, and the electrodes 4b and the land portions 2a are connected to each other through the connection conductors 5.

Next, in a second process, as shown in FIG. 5, the circuit board 1 in which the second semiconductor component 4 has been completely assembled is reversed and the bottom portion of the wall portion 1d of the circuit board 1 is placed on the first jig 7.

Next, the connection conductors 5 provided on the electrodes 3b of the first semiconductor component 3 are placed on the land portions 2a provided on the front surface 1a of the circuit board 1. Thereafter, by pressing the body portion 3a of the first semiconductor component 3 with the second jig 8 in a state where the connection components 5 are heated, the connection conductors 5 are bonded to the land portions 2a, and the electrodes 3b and the land portions 2a are connected to each other through the connection conductors 5.

In this way, the assembly of the first and second semiconductor components 3 and 4 onto both the front and rear surfaces of the circuit board 1 is completed. However, in the first process shown in FIG. 4 and the second process shown in FIG. 5 of the assembly process, the front surface 1a of the circuit board 1 or the lower end of the wall portion 1d serves as a support at the time of thermal compression, so that the first and second semiconductor components 3 and 4 can be reliably bonded.

Therefore, it is not necessary to prepare a plurality of first jigs 7 corresponding to various kinds of circuit boards 1, so that it is possible to obtain an electronic circuit unit with reduced cost and enhanced productivity.

An electronic circuit unit according to a second embodiment of the present invention is shown in FIG. 6. In the second embodiment, at least a pair of wall portions 1d provided to be opposite to each other with a gap therebetween is provided on the rear surface 1b of the circuit board 1, thereby forming the concave portion 1c between the pair of wall portions 1d.

Since the remaining structure is similar to that of the first embodiment, the same elements are denoted by the same reference numerals and descriptions thereof will be omitted.

In the second embodiment, the first and second semiconductor components 3 and 4 can be also assembled using the same method as assembling the first and second semiconductor components 3 and 4 in the first embodiment.

1. An electronic circuit unit comprising a circuit board formed by stacking a plurality of substrates, a wiring pattern having land portions provided on front and rear surfaces of the circuit board, and a semiconductor component disposed on both the front and rear surfaces of the circuit board and connected to the land portions through connection conductors by thermal compression,
wherein a concave portion for housing the semiconductor component is provided on the rear surface of the circuit board, and the semiconductor component is disposed inside the concave portion in a state where the bottom portion of the semiconductor component is not protruded externally from a lower end of the concave portion.

2. The electronic circuit unit according to claim 1, wherein at least a pair of wall portions disposed to be opposite to each other with a gap therebetween is provided on the rear surface of the circuit board, and the concave portion is formed between the pair of wall portions.

3. The electronic circuit unit according to claim 1, wherein a ring-shaped wall portion is provided on the rear surface of the circuit board to surround an outer circumference of the concave portion.

4. The electronic circuit unit according to claim 1, wherein the semiconductor component is made of a flip chip.

5. The electronic circuit unit according to claim 1, wherein the connection conductors are made of metal bumps.
